(19) United States
(12) Patent Application Publication
(10) Pub. No.: US 2023/0271356 A1
(43) Pub. Date: Aug. 31, 2023

(54) FORMING METHOD, FORMING APPARATUS, AND ARTICLE MANUFACTURING METHOD

(71) Applicant: CANON KABUSHIKI KAISHA, Tokyo (JP)

(72) Inventor: TAKAHIRO SATO, Tochigi (JP)

(21) Appl. No.: 18/166,623

(22) Filed: Feb. 9, 2023

(30) Foreign Application Priority Data
Feb. 28, 2022 (JP) 2022-030173

(51) Int. Cl. B29C 43/36; B29C 43/04; B29C 43/52

(52) U.S. Cl. CPC B29C 43/3642; B29C 43/04; B29C 43/52; B29C 2043/3222

(57) ABSTRACT

The present invention provide a forming method of forming a composition on a substrate using a mold, wherein the mold has a contact surface and a cavity, the method comprising: supplying a gas into the cavity so as to increase a pressure in the cavity to deform the contact surface into a convex shape toward the substrate; relatively tilting the mold with respect to the substrate; bringing the contact surface and the composition on the substrate into contact with each other in a state in which the contact surface has been deformed in the supplying the gas and the mold has been tilted in the relatively tilting; and further supplying the gas into the cavity so as to increase a deformation amount of the contact surface after the contact surface and the composition start to contact each other in the bringing.

### BACKGROUND OF THE INVENTION

### Field of the Invention

The present invention relates to a forming method of forming a composition on a substrate, a forming apparatus, and an article manufacturing method.

### Description of the Related Art

There is known a forming technique of forming a composition on a substrate by bringing the composition arranged on the substrate and a mold into contact with each other. Such a forming technique is applicable to an imprint technique and a planarization technique. The imprint technique uses a mold having a contact surface including a pattern with concave and convex portions, and the pattern of the mold can be transferred to a composition on a substrate by curing the composition in a state in which the composition on the substrate and the contact surface are in contact with each other. The planarization technique uses a mold having a flat contact surface, and a film of a composition having a flat upper surface can be formed on a substrate by curing the composition in a state in which the composition on the substrate and the contact surface are in contact with each other.

In the imprint technique and the planarization technique, when the composition on the substrate and the mold are brought into contact with each other, bubbles may remain between the substrate and the mold (that is, in the composition on the substrate). If the composition is cured with the bubbles having entered in the composition, a defect (unfilled defect) can occur in the location where the bubbles exist. To prevent this, the composition on the substrate and the contact surface are brought into contact with each other in a state in which the contact surface of the mold has been deformed into a convex shape toward the substrate by applying a pressure to the mold. With this, the composition on the substrate and the contact surface can be gradually brought into contact with each other from a part of the contact surface of the mold toward the outside so as to extrude the gas between the mold and the substrate to the outside. Thus, bubbles remaining between the mold and the substrate can be reduced.

Further, in order to improve the yield of product chips obtained from the substrate, it is desirable to perform the imprint technique and the planarization technique on a shot region (to be sometimes referred to as a deficient shot region) which is arranged in the peripheral portion of the substrate and comes into contact with only a part of the contact surface. However, for the deficient shot region as described above, when bringing the composition on the substrate and the contact surface of the mold into contact with each other in the state in which the contact surface of the mold has been deformed into the convex shape, the mold comes into contact (collides) with the edge of the substrate, and the mold and/or the substrate may be damaged. An example of the method for avoiding such the contact between the edge of the substrate and the mold is a method of bringing the composition on the substrate and the contact surface of the mold into contact with each other in a state in which the mold has been deformed into a convex shape and tilted with respect to the substrate. Japanese Patent No. 6423641 describes a method of bringing a mold into contact with an imprint material on substrate in a state in which the mold has been deformed into a convex shape and tilted from a posture facing straight with respect to the substrate to a posture tilted with respect to the substrate.

When starting the contact between the contact surface of the mold and the composition on the substrate at a target location on the substrate, if the deformation amount of the contact surface into the convex shape is increased, the tilt amount of the mold with respect to the substrate should be increased accordingly, and the substrate and the mold may come into contact with each other. That is, when starting the contact between the composition on the substrate and the contact surface of the mold in the state in which the mold has been tilted with respect to the substrate, the deformation amount of the contact surface can be limited. As a result, when bringing the composition on the substrate and the mold into contact with each other, bubbles remaining between the substrate and the mold can be insufficiently reduced.

### SUMMARY OF THE INVENTION

The present invention provides, for example, a technique advantageous in accurately forming a composition on a substrate.

According to one aspect of the present invention, there is provided a forming method of forming a composition on a substrate using a mold, wherein the mold has a contact surface that is to be brought into contact with the composition on the substrate and a cavity provided in a surface on an opposite side of the contact surface, the method comprising: supplying a gas into the cavity so as to increase a pressure in the cavity to deform the contact surface into a convex shape toward the substrate; relatively tilting the mold with respect to the substrate; bringing the contact surface and the composition on the substrate into contact with each other in a state in which the contact surface has been deformed in the supplying the gas and the mold has been tilted in the relatively tilting; and further supplying the gas into the cavity so as to increase a deformation amount of the contact surface after the contact surface and the composition start to contact each other in the bringing.

Further features of the present invention will become apparent from the following description of exemplary embodiments with reference to the attached drawings.

### BRIEF DESCRIPTION OF THE DRAWINGS

FIG. 1 is a schematic view showing an example of configurations of an imprint apparatus according to an embodiment;

FIG. 2 is a schematic view showing an example of configurations of a mold driver;

FIG. 3 is a view showing an example of the array of a plurality of shot regions on a substrate;

FIGS. 4A to 4D are views showing a contact process for a full shot region according to a conventional technique;

FIGS. 5A to 5D are views showing a contact process for a deficient shot region according to the conventional technique;

FIGS. 6A to 6D are views showing a contact process according to another conventional technique;

FIGS. 7A to 7C are views for explaining a void occurrence mechanism;

FIGS. 8A to 8C are views for explaining the void occurrence mechanism;

FIGS. 9A to 9D are views showing Example 1 of a contact process for the deficient shot region according to the present invention;

FIG. 10A to 10D are views each showing a modification of the contact process for the deficient shot region according to the present invention;

FIGS. 11A to 11D are views showing Example 2 of the contact process for the deficient shot region according to the present invention;

FIGS. 12A to 12F are views for explaining an article manufacturing method; and

FIGS. 13A to 13D are views for explaining a planarization process.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which directions parallel to the surface of a substrate are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving (movement) concerning the X-axis, the Y-axis, and the Z-axis means control or driving (movement) concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively.

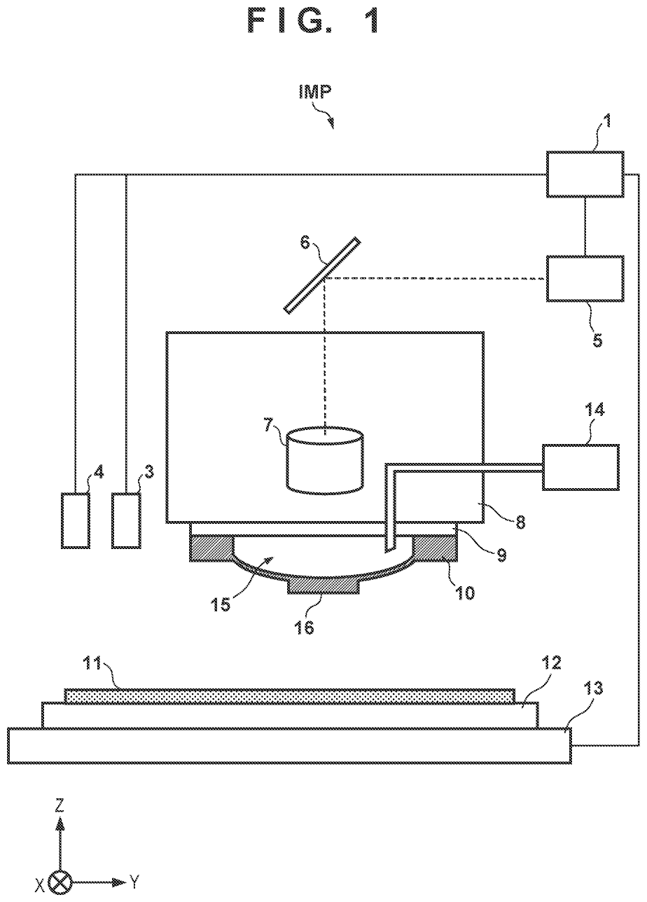

FIG. 1 is a schematic view showing an example of configurations of an imprint apparatus IMP in an embodiment according to the present invention. The imprint apparatus IMP is a lithography apparatus that is employed in a lithography step, which is a manufacturing step of a semiconductor device, a magnetic storage medium, a liquid crystal display element, or the like, and forms a pattern on a substrate. The imprint apparatus IMP functions as a forming apparatus used to perform a forming process of forming a curable composition (composition) on a substrate using a mold, and performs, as the forming process, an imprint process of forming an imprint material serving as the curable composition. More specifically, the imprint apparatus IMP brings the mold and the imprint material supplied (arranged) onto the substrate into contact with each other and applies curing energy to the imprint material, thereby forming a pattern of a cured product to which a pattern of the mold has been transferred. Note that the mold is sometimes referred to as a template or an original.

The imprint process performed by the imprint apparatus IMP will be described below while describing configurations of the imprint apparatus IMP according to this embodiment with reference to FIG. 1. The imprint process is controlled by a controller 1. The controller 1 is formed by, for example, a computer including a processor such as a CPU and a storage unit such as a memory, and controls the imprint process by controlling respective units of the imprint apparatus IMP.

In the imprint apparatus IMP, a substrate 11 serving as a target of the imprint process is arranged on a substrate holder 12 (substrate chuck). Then, the imprint apparatus IMP causes a substrate driver 13 supporting the substrate holder 12 to drive the substrate 11 in the X and Y directions so as to arrange, below a supplier 3, a target shot region on which the imprint process is performed among a plurality of shot regions on the substrate 11. The supplier 3 (dispenser) is a mechanism that supply (discharge) an imprint material onto the substrate by discharging the imprint material (curable composition) toward the substrate 11. The imprint apparatus IMP can supply the imprint material onto the substrate by causing the supplier 3 to discharge the imprint material while causing the substrate driver 13 to move the substrate 11 below the supplier 3. The position of the substrate driver 13 (substrate 11) in the X and Y directions is measured by a measurement unit 4, and controlled by the controller 1 based on the measurement result of the measurement unit 4.

As the material of the substrate 11, for example, glass, ceramic, a metal, a semiconductor, a resin, or the like is used. A member made of a material different from that of the substrate may be provided on the surface of the substrate, as needed. The substrate 11 is, for example, a silicon wafer, a compound semiconductor wafer, or silica glass.

As the imprint material, a curable composition (to be also referred to as a resin in an uncured state) to be cured by receiving curing energy is used. The curable composition is a composition cured by light irradiation or heating. Among these, a photo-curable composition cured by light irradiation contains at least a polymerizable compound and a photopolymerization initiator, and may further contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component. The viscosity (the viscosity at 25° C.) of the viscous material is, for example, from 1 mPa·s (inclusive) to 100 mPa·s (inclusive).

Here, in this embodiment, the imprint material supplying process can be performed only on the target shot region, but it may be performed on two or more shot regions among the plurality of shot regions on the substrate 11 at once (collectively). The supplier 3 that performs the imprint material supplying process can be provided as a component of the imprint apparatus IMP, but it may be provided as an outer mechanism of the imprint apparatus IMP. In this case, the imprint material supplying process can be performed on the entire surface of the substrate 11 in advance before loading the substrate 11 to the imprint apparatus IMP.

After the imprint material supplying process, the substrate driver 13 drives the substrate 11 to arrange a part of the target shot region or the entire target shot region on the substrate 11 below a mold 10 (contact surface 16). The mold 10 is held by a mold holder 9 (mold chuck), and can be driven in the Z direction by a mold driver 8. By driving the mold 10 to the substrate 11 side (−Z direction), the mold 10 and the imprint material on the substrate 11 can start to contact each other. The process from the arrangement of the substrate 11 below the mold 10 by the substrate driver 13 to the start of contact between the mold 10 and the substrate 11 by the mold driver 8 is sometimes generically referred to as a “contact starting process” in this embodiment. Further, the contact starting process is sometimes referred to as a liquid contact process.

The mold 10 has, for example, a rectangular outer shape, and can be normally made of a material such as quartz that can transmit ultraviolet light. A mesa portion formed in a mesa shape having a step of, for example, about several ten μm is provided on the substrate side of the mold 10, and the surface of the mesa portion on the substrate side functions as the contact surface 16 that is to be brought into contact with the imprint material on the substrate. In the mold 10 used in the imprint apparatus IMP according to this embodiment, the contact surface 16 is formed as a pattern surface on which a pattern with concave and convex portions (device pattern or circuit pattern) that is to be transferred to the imprint material on the substrate has been formed. Note that in a mold used in a planarization apparatus, the contact surface 16 is formed as a flat surface with no pattern with concave and convex portions formed thereon.

Further, a cavity 15 (concave portion) is formed in the surface of the mold 10 on the opposite side of the contact surface 16 so as to reduce the thicknesses of the contact surface 16 and the surrounding portion. The cavity 15 becomes an almost sealed space (gas chamber) when the mold 10 is held by the mold holder 9. The cavity 15 is connected to a mold deforming unit 14 via a pipe.

In the contact starting process, the pressure in the cavity is controlled by controlling the supply amount of a gas into the cavity 15 (gas chamber) of the mold 10 by the mold deforming unit 14, thereby deforming the contact surface 16 of the mold 10 into a convex shape bending toward the substrate 11. The mold deforming unit 14 may be understood as a gas supplier that supplies a gas into the cavity 15 so as to deform the contact surface 16 of the mold 10 into a convex shape. For example, the mold deforming unit 14 supplies a compressed gas into the cavity 15 in the contact starting process, thereby making the pressure in the cavity 15 higher than the pressure outside the cavity 15. With this, the contact surface 16 of the mold 10 is deformed into the convex shape, so that the mold 10 and the imprint material on the substrate can be gradually brought into contact with each other from a part (for example, central portion) of the contact surface 16 toward the outside. As a result, bubbles remaining between the mold 10 and the substrate 11 (that is, in the imprint material on the substrate) can be reduced, and defects of the pattern formed in the imprint material on the substrate can be reduced. Such the bubble reduction effect increases as the deformation amount of the mold 10 into the convex shape increases.

After the contact surface 16 of the mold 10 and the imprint material on the substrate 11 start to contact each other in the contact starting process, in order to increase the contact surface therebetween, the mold driver 8 further drives the mold 10 to the substrate 11 side (−Z direction). This driving can be performed by force control based on the force (reaction force) received by the mold 10 from the imprint material on the substrate 11, but may be performed by position control based on the Z-direction distance between the mold 10 and the substrate 11. Then, the pressure control of the cavity 15 and the control of the mold driver 8 are performed in parallel until the imprint material on the substrate 11 spreads over the entire region of the contact surface 16 of the mold 10. The process performed after the contact surface 16 of the mold 10 and the imprint material on the substrate 11 start to contact each other until the imprint material spreads over the entire region of the contact surface 16 of the mold 10 is sometimes generically referred to as a “pressing process” in this embodiment. Further, the contact starting process and the pressing process are sometimes collectively referred to as a “contact process”. In the contact process, alignment (overlay) between the contact surface 16 of the mold 10 and the target shot region on the substrate 11 in the X and Y directions may be performed.

Here, the contact process is not limited to driving the mold 10 to the substrate 11 side (−Z direction) by the mold driver 8, but may be performed by driving the substrate 11 to the mold 10 side (+Z direction) by the substrate driver 13. Alternatively, the contact process may be performed by relatively driving the mold 10 and the substrate 11 by the mold driver 8 and the substrate driver 13. In the contact process in this embodiment, the method of using the mold driver 8 is described. However, the present invention can be similarly applied to the method of using the substrate driver 13 or the method of using both the mold driver 8 and the substrate driver 13.

The substrate driver 13 and the mold driver 8 form a driving mechanism that drives at least one of the substrate 11 and the mold 10 so as to adjust the relative position between the substrate 11 and the contact surface 16. Relative position adjustment by the driving mechanism includes driving for bringing the contact surface 16 of the mold 10 into contact with the imprint material on the substrate and separating the contact surface 16 from the cured product of the imprint material on the substrate. The substrate driver 13 can be configured to drive the substrate 11 for a plurality of axes (for example, three axes including the X-axis, the Y-axis, and the θZ-axis, and preferably, six axes including the X-axis, the Y-axis, the Z-axis, the θX-axis, the θY-axis, and the θZ-axis). The mold driver 8 is configured to drive the mold 10 for a plurality of axes (for example, three axes including the Z-axis, the θX-axis, and the θY-axis, and preferably, six axes including the X-axis, the Y-axis, the Z-axis, the θX-axis, the θY-axis, and the θZ-axis).

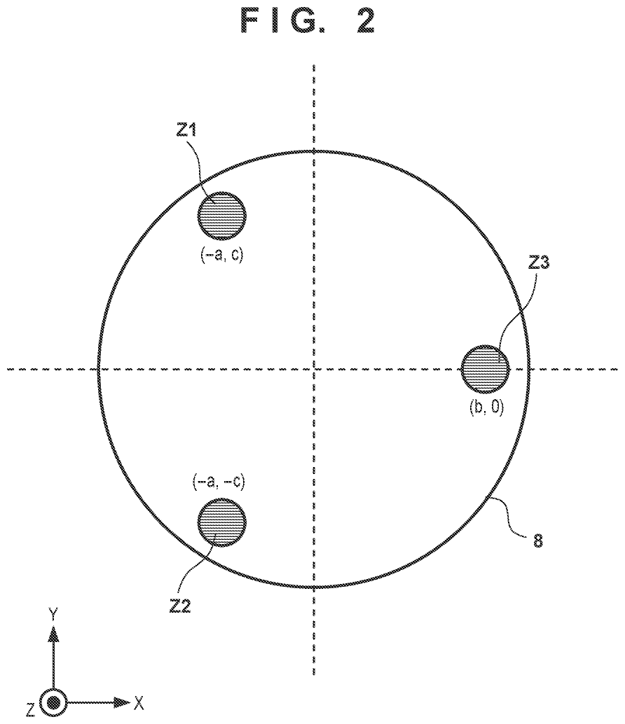

As exemplarily shown in FIG. 2, the mold driver 8 can include three driving systems Z1, Z2, and Z3 that drive the mold holder 9 (mold 10) in the Z direction. In FIG. 2, examples of coordinates at which the driving systems Z1, Z2, and Z3 are arranged are shown in parentheses. Each of the driving systems Z1, Z2, and Z3 includes, for example, a sensor that detects the position in the Z direction and/or the force acting in the Z direction. Based on outputs from these sensors, the position and posture (tilt) of the mold 10 and the force applied to the mold 10 can be controlled. For example, when the driving systems Z1 and Z2 drive the mold 10 to the substrate 11 side (−Z direction) and the driving system Z3 drives the mold 10 to the opposite side (+Z direction) of the substrate 11, the mold 10 can be tilted to the θY direction (the rotation direction about the axis parallel to the Y-axis). With this, it is possible to control the tilt of the mold 10 (contact surface 16) with respect to the substrate 11 and/or the posture of the mold 10 in accordance with the in-plane shape. That is, the mold driver 8 functions as a tilt changer that changes the tilt of the mold 10 with respect to the substrate 11.

After the imprint material spreads over the entire region of the contact surface 16 of the mold 10, the imprint material is cured by applying the curing energy to the imprint material in a state in which the contact surface 16 and the imprint material on the substrate 11 are in contact with each other. As the curing energy, an electromagnetic wave or heat is used. The electromagnetic wave is, for example, light selected from the wavelength range of 10 nm (inclusive) to 1 mm (inclusive), for example, infrared rays, visible light, or ultraviolet light. In this embodiment, the curing energy is light (for example, ultraviolet light). The curing energy is emitted from a light source 5, and applied to the imprint material on the substrate 11 through a beam splitter 6, a relay optical system 7, and the mold 10. The process of curing the imprint material after the imprint material spreads over the entire region of the contact surface 16 of the mold 10 is sometimes generically referred to as a “curing process (exposure process)” in this embodiment.

After curing the imprint material, the contact surface 16 of the mold 10 is separated from the cured imprint material by driving the mold driver 8 to the opposite side (+Z direction) of the substrate 11. Thus, a pattern made of a cured product of the imprint material can be formed on the target shot region on the substrate 11. The process of separating the contact surface 16 of the mold 10 from the imprint material after the imprint material is cured is sometimes generically referred to as a “mold separation process” in this embodiment.

The above-described imprint process (contact process (contact starting process and pressing process), curing process, and mold separation process) can be performed for each of the plurality of shot regions on the substrate 11. For example, if another shot region on which the imprint process is to be performed exists in the same substrate 11 and the imprint material has not been supplied onto the other shot region, the imprint material supplying process is performed on the other shot region. Then, after driving the substrate 11 by the substrate driver 13 so as to arrange the other shot region below the mold 10 (contact surface 16), the imprint process (contact process, curing process, and mold separation process) is performed on the other shot region serving as the target shot region. On the other hand, if another shot region on which the imprint process is to be performed does not exist in the same substrate 11, the substrate 11 is unloaded from the substrate holder 12.

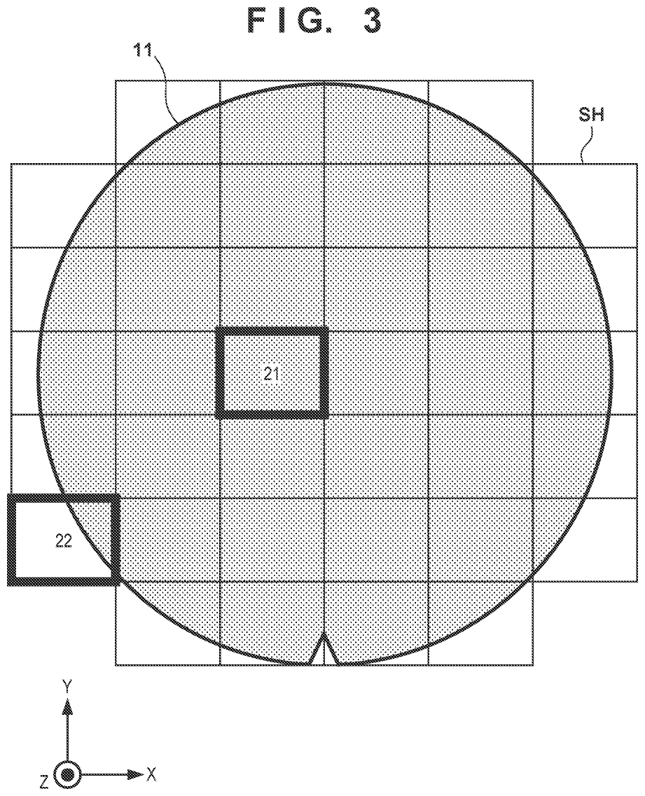

Here, in order to improve the yield of product chips obtained from the substrate 11, it is desirable to perform the imprint process not only on a full shot region but also on a deficient shot region. The full shot region is a shot region which is arranged in the central portion of the substrate 11 and comes into contact with the entire contact surface 16 of the mold 10. The full shot region is sometimes referred to as an entire shot region or a complete shot region. The deficient shot region is a shot region which is arranged in the periphery portion of the substrate 11 and comes into contact with only a part of the contact surface 16 of the mold 10. The deficient shot region is sometimes referred to as a partial shot region. FIG. 3 shows an example of the array of a plurality of shot regions SH on the substrate 11. In FIG. 3, a shot region 21 represents an example of the full shot region, and a shot region 22 represents an example of the deficient shot region.

In the contact process, with respect to the deficient shot region 22 as described above, the center portion (that is, the portion at the lowest point) of the contact surface 16 of the mold 10 deformed into the convex shape by the mold deforming unit 14 may be located outside the substrate 11. In this case, in the contact process, the contact surface 16 of the mold 10 comes into contact (collides) with the edge of the substrate 11, and the mold and/or the substrate can be damaged. That is, this can be a factor that causes a difference between the imprint process on the full shot region 21 and the imprint process on the deficient shot region 22.

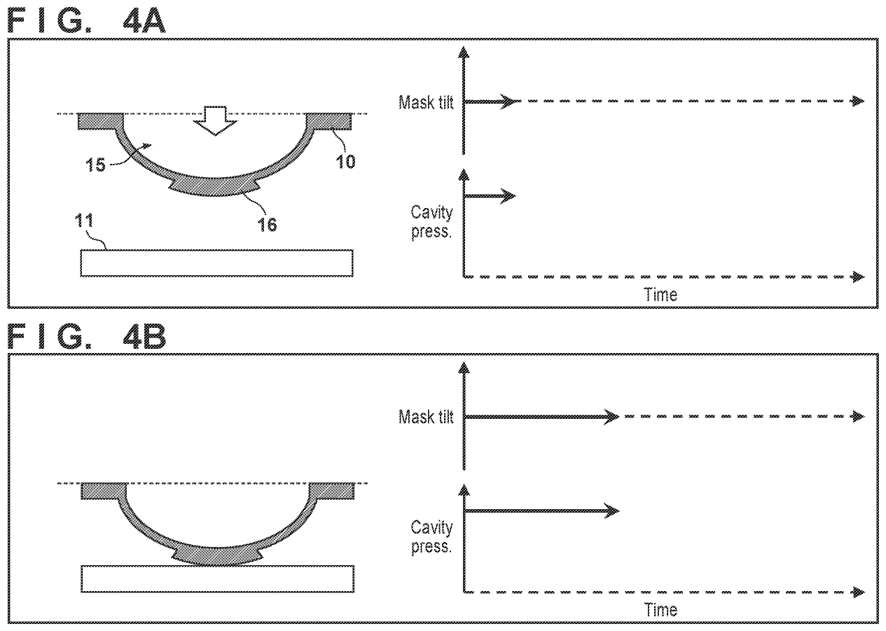

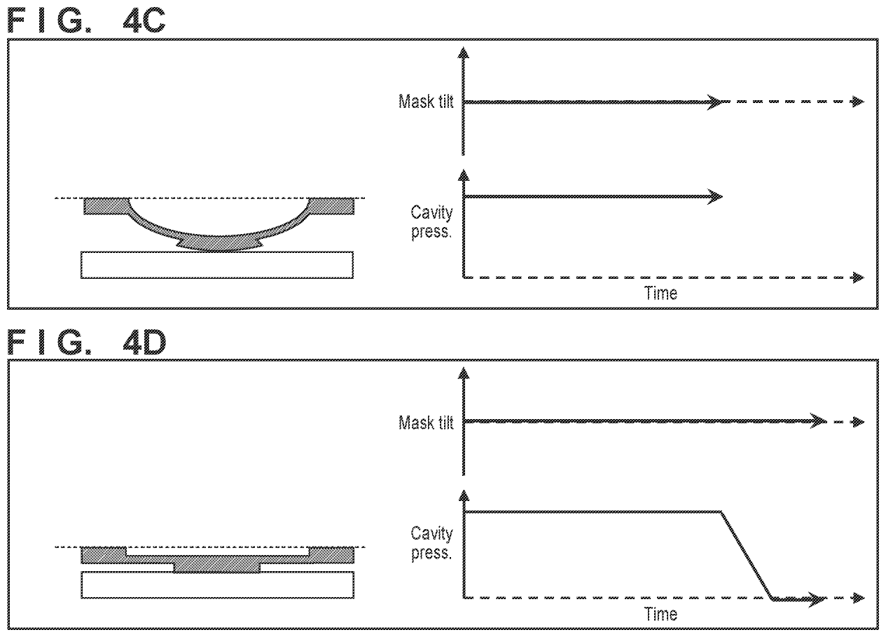

FIGS. 4A to 4D show a conventional technique, and explain, using schematic views and graphs, changes of the posture (tilt) of the mold 10 and the pressure in the cavity 15 in a case of performing the contact process (contact starting process and pressing process) on the full shot region 21. In the following description, the pressure in the cavity 15 may be understood as the amount (supply amount) of the gas supplied into the cavity 15 by the mold deforming unit 14 to deform the contact surface 16 of the mold 10 into the convex shape. Further, for the sake of illustrative simplicity, the imprint material on the substrate is not illustrated in each drawing described below.

FIG. 4A shows the state in the contact starting process (that is, before the contact surface 16 of the mold 10 and the substrate 11 start to contact each other). In FIG. 4A, the mold 10 has the posture facing straight with respect to the substrate 11 or adjusted for overlay with the substrate 11. That is, the relative tilt between the mold 10 and the substrate 11 has been adjusted so as to make the mold 10 and the substrate 11 parallel to each other. Further, in order to deform the contact surface 16 of the mold 10 into the convex shape, the gas has been supplied into the cavity 15 by the mold deforming unit 14 at a maximum pressure to the extent that the mold 10 does not come off from the mold holder 9 due to a gas (air) entering from the outside. That is, the deformation amount of the contact surface 16 of the mold 10 is maximum due to the configuration of the imprint apparatus IMP. With this, the effect of reducing bubbles remaining between the mold 10 and the substrate 11 can be maximized.

FIGS. 4B to 4D show the pressing process divided into the earlier stage, the middle stage, and the later stage in the chronological order. In FIGS. 4B and 4C, the pressure in the cavity 15 remains high and pressing of the mold 10 by the mold driver 8 is controlled, thereby spreading the imprint material on the contact surface 16 of the mold 10. During this process, the posture of the mold 10 slightly changes from the posture in FIG. 4A due to disturbance, but is controlled to the posture facing straight with respect to the substrate 11 or adjusted for overlay with the substrate 11 as the target posture.

In FIG. 4D, in order to spread the imprint material over the entire contact surface 16 of the mold 10, the pressure in the cavity 15 is decreased to make the contact surface 16 of the mold 10 deformed into the convex shape become the shape facing straight with respect to the substrate 11 or adjusted for overlay with the substrate 11. That is, the gas in the cavity 15 is decreased so as to decrease the deformation amount of the contact surface 16 of the mold 10 and make the contact surface 16 and the upper surface of the substrate 11 parallel to each other. During this process as well, as in FIGS. 4B and 4C, the posture of the mold 10 slightly changes from the postures in FIGS. 4A to 4C due to disturbance, but is controlled to the posture facing straight with respect to the substrate 11 or adjusted for overlay with the substrate 11 as the target posture.

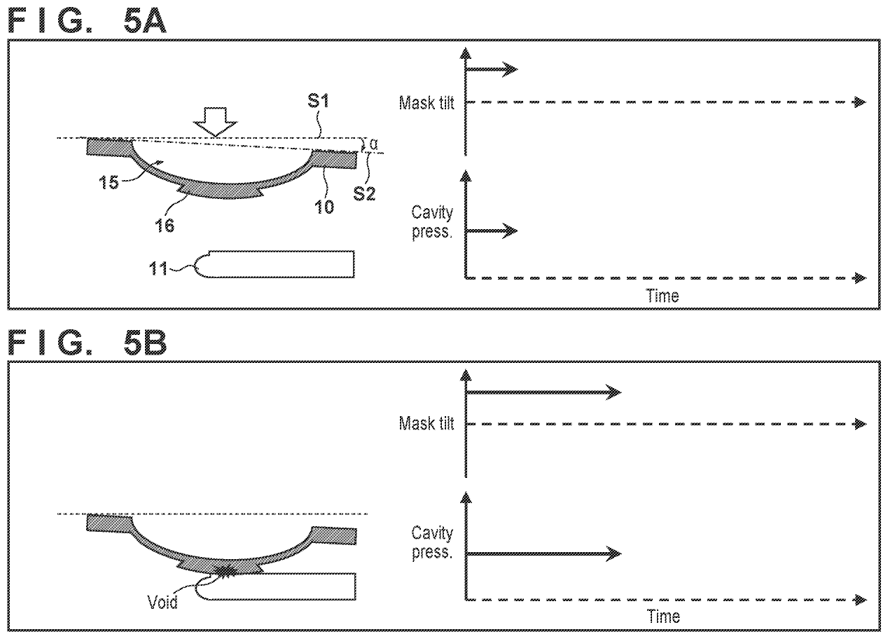

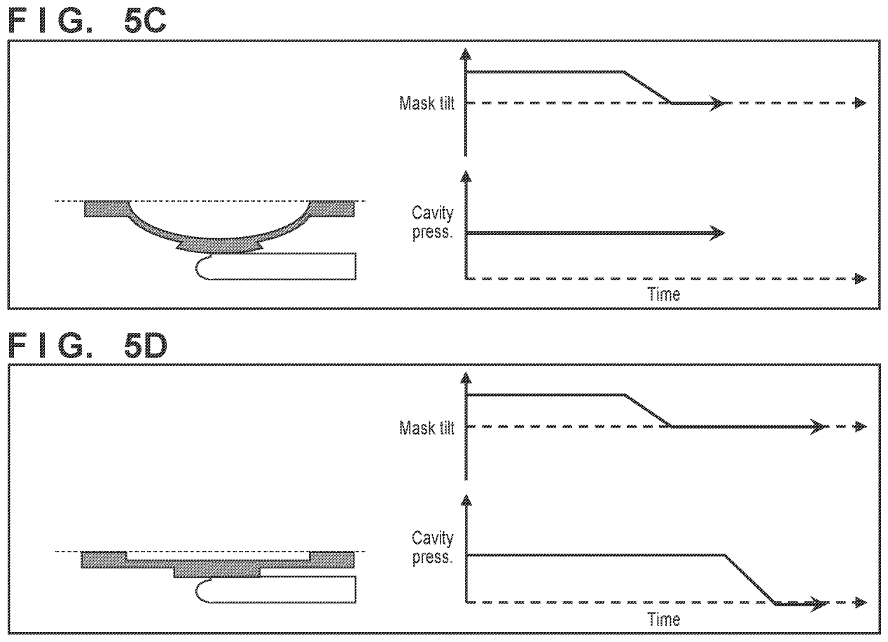

FIGS. 5A to 5D show the conventional technique, and explain, using schematic views and graphs, changes of the posture (tilt) of the mold 10 and the pressure in the cavity 15 in a case of performing the contact process (contact starting process and pressing process) on the deficient shot region 22. In the contact process on the deficient shot region 22, in order to start the contact between the contact surface 16 of the mold 10 and the imprint material on the deficient shot region 22 at a target location in the deficient shot region 22, the mold 10 is relatively tilted with respect to the substrate 11 by the mold driver 8.

FIG. 5A shows the state in the contact starting process (that is, before the contact surface 16 of the mold 10 and the substrate 11 start to contact each other). The mold 10 is relatively tilted with respect to the substrate 11 by the mold driver 8 such that the contact surface 16 faces outward from the substrate 11. The relative tilt amount of the mold 10 with respect to the substrate 11 can be defined as, for example, an amount a of tilting a surface S2 (held surface) of the mold 10 held by the mold holder 9 with respect to a reference surface S1 parallel to the upper surface of the substrate 11. Further, in order to deform the contact surface 16 of the mold 10 into the convex shape, the gas is supplied into the cavity 15 by the mold deforming unit 14. By simply deforming the contact surface 16 of the mold 10 into the convex shape, the lowest point of the contact surface 16 is located outside the substrate 11. Therefore, in order to shift the lowest point of the contact surface 16 to the inside (target location) in the substrate 11, the mold 10 is tilted with respect to the substrate 11. In this state, when the mold 10 is driven toward the substrate 11, the contact surface 16 can first come into contact with the imprint material on the substrate at the target location in the deficient shot region 22.

Here, in the contact starting process on the deficient shot region 22, the pressure in the cavity 15 is set at a lower value than in the contact starting process on the full shot region 21. This is because, when starting the contact between the contact surface 16 and the imprint material at the target location in the deficient shot region 22, if the deformation amount of the contact surface 16 is increased, the tilt amount of the mold 10 with respect to the substrate 11 should be largely increased accordingly. If the tilt amount of the mold 10 with respect to the substrate 11 is increased, the mold 10 (for example, the edge of the mold 10 itself) and the substrate 11 are more likely to come into contact with each other.

In FIG. 5B, as in the case of the full shot region 21, pressing of the mold 10 by the mold driver 8 is controlled while maintaining the pressure in the cavity 15, thereby spreading the imprint material on the contact surface 16 of the mold 10. At this time, in the contact starting process on the deficient shot region 22, the pressure in the cavity 15 is lower (that is, the deformation amount of the contact surface 16 is smaller) than that in the case of the full shot region 21. Therefore, bubbles easily enter between the contact surface 16 of the mold 10 and the substrate 11. That is, a void (unfilled defect) easily occurs.

Thereafter, in FIG. 5C, while spreading the imprint material by controlling pressing of the mold 10 by the mold driver 8, the posture of the mold 10 is returned to the posture facing straight with respect to the substrate 11 or adjusted for overlay with the substrate 11. That is, in FIG. 5C, the tilt amount (posture) of the mold 10 changed in FIG. 5A is returned so as to make the mold 10 and the substrate 11 parallel to each other, for example, so as to make the held surface S2 of the mold 10 match the reference surface S1. In addition, in FIG. 5D, the deformation amount of the contact surface 16 is decreased by decreasing the gas in the cavity 15 (that is, the pressure in the cavity 15) by the mold deforming unit 14 so as to make the contact surface 16 of the mold 10 and the substrate 11 (upper surface) parallel to each other.

In this manner, in the contact starting process on the deficient shot region 22, since the mold 10 is tilted with respect to the substrate 11, the deformation amount for deforming the contact surface 16 of the mold 10 into the convex shape is limited accordingly. As a result, bubbles easily enter between the mold 10 and the substrate 11 upon spreading the imprint material on the contact surface 16 of the mold 10, and a void (unfilled defect) can be more likely to occur.

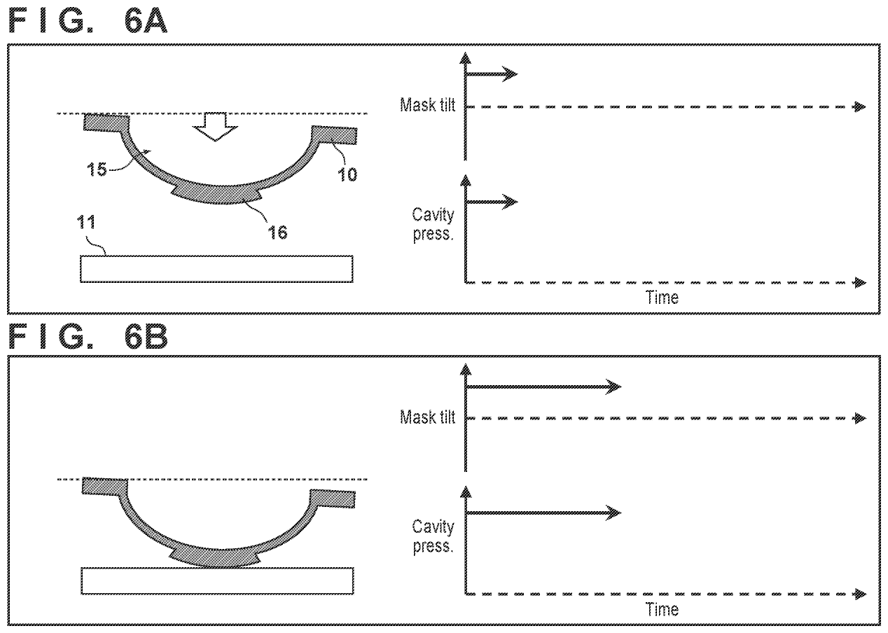

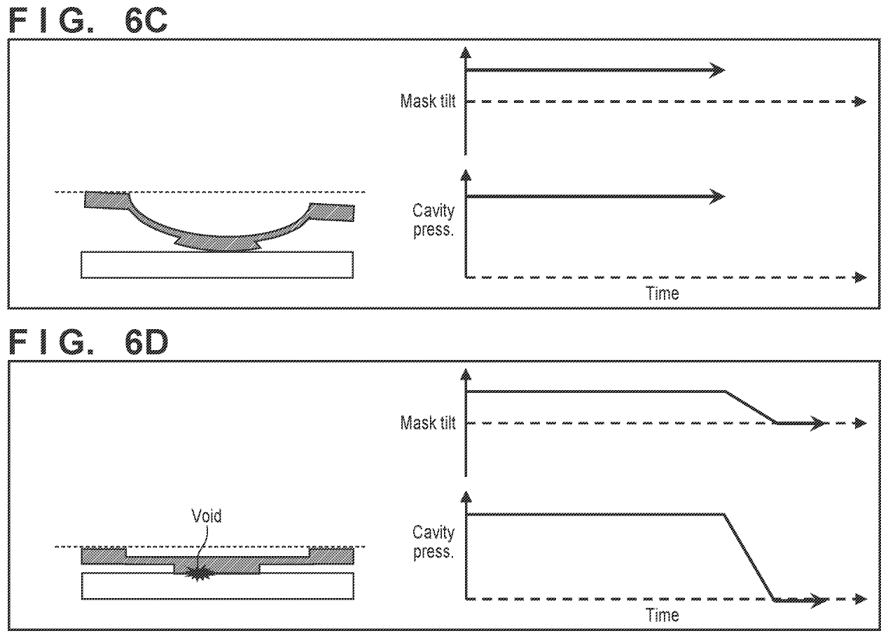

FIG. 6A to 6D show another conventional technique, and explain, using schematic views and graphs, changes of the posture (tilt) of the mold 10 and the pressure in the cavity 15. For the sake of descriptive simplicity of the problem in the conventional technique, FIGS. 6A to 6D exemplarily show a case of the full shot region 21 in which the mold 10 is tilted by the amount similar to that in the case of the deficient shot region 22.

FIG. 6A shows the state in the contact starting process. In FIG. 6A, the tilt amount (posture) of the mold 10 with respect to the substrate 11 is similar to that in the example shown in FIG. 5A, and the pressure in the cavity 15 is similar to that in the example shown FIG. 4A.

In FIGS. 6B and 6C, pressing of the mold 10 by the mold driver 8 is controlled while maintaining the tilt amount (posture) of the mold 10, thereby spreading the imprint material on the contact surface 16 of the mold 10. In this example, different from the example shown in FIG. 5B, the pressure in the cavity 15 is maintained to be high as in the example shown in FIG. 4B. Therefore, during the contact starting process, bubbles entering between the contact surface 16 of the mold 10 and the substrate 11 are reduced.

Here, in order to spread the imprint material over the entire contact surface 16 of the mold 10, the posture of the mold 10 should be returned to the posture facing straight with respect to the substrate 11 or adjusted for overlay with the substrate 11 at some timing. That is, the tilt amount (posture) of the mold 10 changed in FIG. 6A should be returned so as to make the mold 10 and the substrate 11 parallel to each other, that is, so as to make the held surface S2 of the mold 10 match the reference surface S1. Therefore, in FIG. 6D, the posture of the mold 10 is returned while decreasing the deformation amount of the contact surface 16 by decreasing the gas in the cavity 15 (that is, the pressure in the cavity 15) by the mold deforming unit 14. However, if the posture of the mold 10 is returned while decreasing the deformation amount of the contact surface 16 as shown in FIG. 6D, a void can occur as in FIG. 5B.

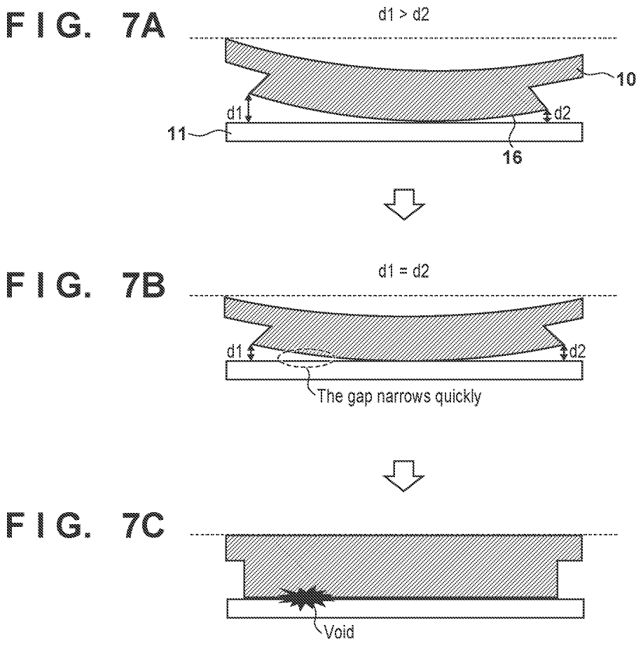

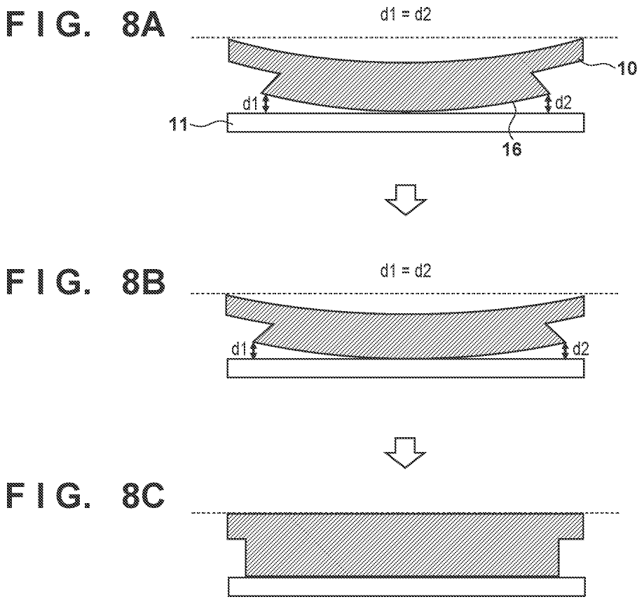

The mechanism in which the void occurs in FIGS. 6C and 6D will be described below with reference to FIGS. 7A to 7C and FIGS. 8A to 8C. Each of FIGS. 7A to 7C shows an enlarged view near the contact surface 16 in the example shown in FIGS. 6A to 6D. FIG. 7A corresponds to FIG. 6C, and FIG. 7C corresponds to FIG. 6D. FIG. 7B shows a state between FIG. 7A and FIG. 7C. Each of FIGS. 8A to 8C shows an enlarged view near the contact surface 16 in the example shown in FIGS. 4A to 4D for the sake of comparison with FIGS. 7A to 7C. FIG. 8A corresponds to FIG. 4C, and FIG. 8C corresponds to FIG. 4D. FIG. 8B shows a state between FIG. 8A and FIG. 8C.

FIG. 7A shows the state in which the imprint material is spread on the contact surface 16 of the mold 10 while tilting the mold 10 in the state in which the contact surface 16 of the mold 10 has been deformed into the convex shape by increasing the pressure in the cavity 15. At this time, a difference occurs between a distance d1 from one edge of the contact surface 16 to the substrate 11 and a distance d2 from the other edge of the contact surface 16 to the substrate 11. In the contact process, quickly decreasing the distance between the contact surface 16 and the substrate 11 can increase the risk of trapping, between the contact surface 16 and the substrate 11, bubbles that can cause a void.

Next, FIG. 7B shows the state in which the tilt of the mold 10 is returned while decreasing the pressure in the cavity 15. By controlling the pressure in the cavity 15 and the tilt of the mold 10 in this manner, the distance d1 and the distance d2 can be made to be similar to each other. However, paying attention to the change in the distance d1, the change amount in the distance d1 is larger by the tilt amount of the mold 10 than that in the example shown in FIGS. 8A to 8C (the example of performing the contact process without tilting the mold 10). As a result, as shown in FIG. 7C, bubbles are likely to be trapped between the contact surface 16 and the substrate 11, and a void easily occurs.

The problems in the conventional techniques for the deficient shot region 22 have been described above. According to the description, in order to form the imprint material on the substrate 11 in the deficient shot region 22 with the processing time (sequence time) similar to that required for the full shot region 21 and with reduced void occurrence, the following two requirements are required.

(1) The deformation amount (convex shape) of the contact surface 16 is increased immediately after the contact surface 16 of the mold 10 and the imprint material on the substrate 11 start to contact each other.

(2) The posture of the mold 10 is returned in a state in which the deformation amount (convex shape) of the contact surface 16 is large.

Accordingly, in the imprint process (contact process) according to this embodiment, the contact surface 16 and the imprint material on the substrate 11 are brought into contact with each other in a state in which the contact surface 16 of the mold 10 has been deformed into the convex shape and the mold 10 has been tilted with respect to the substrate 11. Then, after the contact surface 16 and the imprint material on the substrate 11 start to contact each other, a gas increasing step of further supplying the gas into the cavity 15 so as to increase the deformation amount of the contact surface 16 is performed. With this, it is possible to reduce voids occurring as described in the example shown in FIG. 5B.

Further, in the imprint process according to this embodiment, a gas decreasing step of decreasing the gas in the cavity 15 so as to decrease the deformation amount of the contact surface 16 and a tilt decreasing step of decreasing the tilt of the mold 10 with respect to the substrate 11 (that is, returning the tilt of the mold 10) are performed. The gas decreasing step is performed after the gas increasing step. The tilt decreasing step is performed in a period from the start of the gas increasing step to the start of the gas decreasing step. With this, it is possible to decrease the void generated as described in the example shown in FIG. 6D.

### Example 1

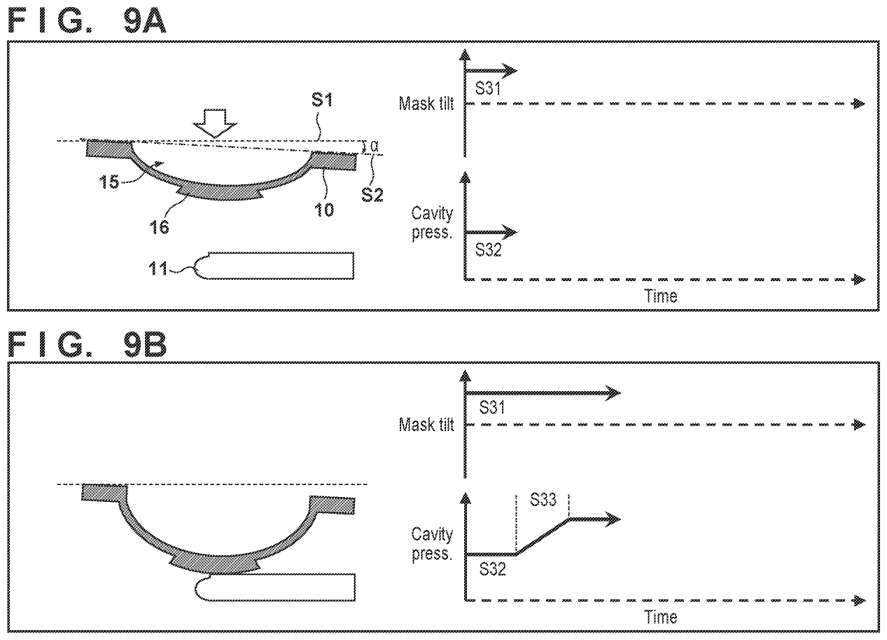

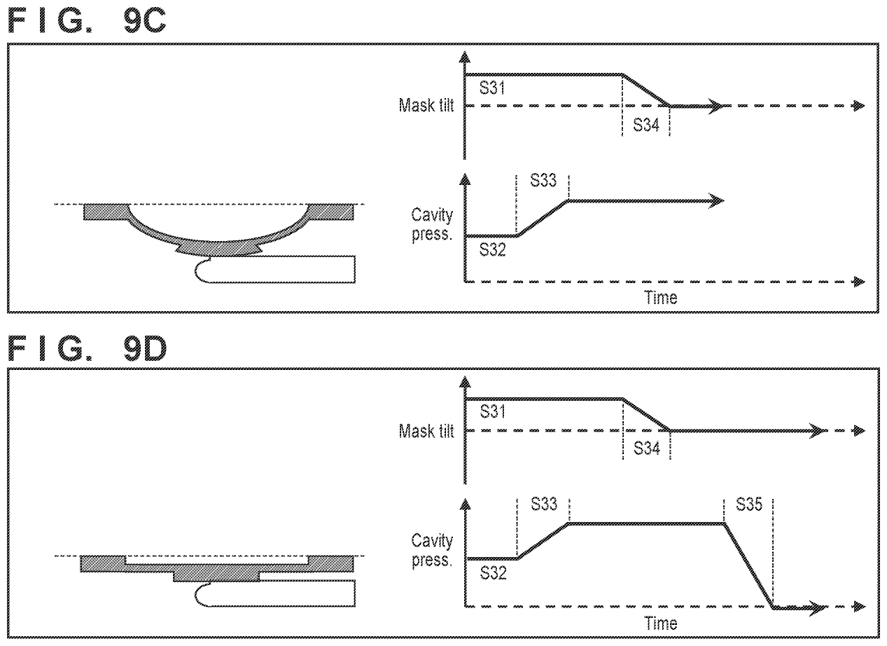

Example 1 according to the present invention will be described below. FIGS. 9A to 9D show Example 1 according to this embodiment, and explain, using schematic views and graphs, changes of the posture (tilt) of the mold 10 and the pressure in the cavity 15 in a case of performing the contact process (contact starting process and pressing process) on the deficient shot region 22. As has been described above, the pressure in the cavity 15 may be understood as the amount (supply amount) of the gas supplied into the cavity 15 by the mold deforming unit 14 to deform the contact surface 16 of the mold 10 into the convex shape. Further, for the sake of illustrative simplicity, the imprint material on the substrate is not illustrated in each drawing described below.

FIG. 9A shows the state in the contact starting process. The mold 10 is relatively tilted with respect to the substrate 11 by the mold driver 8 such that the contact surface 16 faces outward from the substrate 11 (tilt changing step S31). Further, the mold deforming unit 14 supplies the gas into the cavity 15 so as to increase the pressure in the cavity 15 to deform the contact surface 16 of the mold 10 into the convex shape (gas supplying step S32). In this state, the mold driver 8 drives the mold 10 in the −Z direction so as to narrow the gap between the mold 10 and the substrate 11, thereby bringing the contact surface 16 of the mold 10 and the imprint material on the substrate into contact with each other. Here, as in the example shown in FIG. 5A described above, the pressure in the cavity 15 is set at a lower value than that in the case of the full shot region 21. The reason for this is as described with reference to FIG. 5A.

FIG. 9B shows the state immediately after the contact surface 16 of the mold 10 and the imprint material on the substrate start to contact each other. After the contact surface 16 and the imprint material on the substrate start to contact each other, the gas is further supplied into the cavity 15 so as to increase the pressure in the cavity 15 and increase the deformation amount of the contact surface 16 (gas increasing step S33). By increasing the gas in the cavity 15 to increase the convex shape (deformation amount) of the contact surface 16 in this manner, it is possible to spread the imprint material while preventing bubbles trapped between the contact surface 16 of the mold 10 and the substrate 11.

FIG. 9C shows the state in which pressing by the mold driver 8 is controlled by the contact surface 16, whose convex shape has been increased by increasing the pressure in the cavity 15 in FIG. 9B in the preceding stage, thereby spreading the imprint material on the contact surface 16. Further, during this process, the posture of the mold 10 is returned by decreasing the tilt of the mold 10 with respect to the substrate 11 (tilt decreasing step S34). That is, the posture of the mold 10 is returned from the posture tilted outward from the substrate 11 to the posture facing straight with respect to the substrate 11 or adjusted for overlay with the substrate 11. With this step, it can be said that the posture (tilt) of the mold 10 and the convex shape of the contact surface 16 become similar to those in FIG. 4C which shows the example of the full shot region 21 with relatively little void occurrence. In this manner, when the convex shape of the contact surface 16 is increased in FIG. 9B in the preceding stage and then the posture of the mold 10 is returned in this state, it is possible to reduce (prevent) void occurrence caused by bubbles trapped between the contact surface 16 of the mold 10 and the substrate 11.

In FIG. 9D, in order to spread the imprint material over the entire contact surface 16 of the mold 10, the pressure in the cavity 15 is decreased to make the contact surface 16 deformed into the convex shape become the shape facing straight with respect to the substrate 11 or adjusted for overly with the substrate 11. That is, so as to make the contact surface 16 and the substrate 11 parallel to each other, the mold deforming unit 14 decreases the gas in the cavity 15, thereby decreasing the pressure in the cavity 15 and decreasing the deformation amount of the contact surface 16 of the mold 10 (gas decreasing step S35). During this process, as in FIGS. 4B and 4C, the posture of the mold 10 slightly changes due to disturbance, but is controlled to the posture facing straight with respect to the substrate 11 or adjusted for overlay with the substrate 11 as the target posture.

The imprint process (contact process) of Example 1 described with reference to FIGS. 9A to 9D satisfies the above-described two requirements ((1) the deformation amount (convex shape) of the contact surface 16 is increased immediately after the contact surface 16 of the mold 10 and the imprint material on the substrate 11 start to contact each other, and (2) the posture of the mold 10 is returned in a state in which the deformation amount (convex shape) of the contact surface 16 is large). Therefore, with the imprint process (contact process) of Example 1, it is possible to form the imprint material on the substrate 11 in the deficient shot region 22 with the processing time similar to that required for the full shot region 21 and with reduced void occurrence.

Here, in FIGS. 9A to 9D, an example has been described in which the process is performed in the order of “increasing the pressure in the cavity 15 starts”→“increasing the pressure in the cavity 15 ends”→“returning the posture of the mold 10 starts”→“returning the posture of the mold 10 ends”, but the present invention is not limited to this. For example, depending on the demanded processing time (sequence time), the allowable size of the void, and the allowable number of voids, the orders and timings of the pressure control of the cavity 15 and the posture control of the mold 10 can be changed. However, it is the requirement that tilt decreasing step S34 is performed in a period from the start of gas increasing step S33 to the start of gas decreasing step S35. Each of FIGS. 10A to 10D shows the imprint process (contact process) for the deficient shot region 22 performed in the order different from that shown in FIGS. 9A to 9D, that is, a modification of the imprint process (contact process) for the deficient shot region 22.

FIG. 10A shows an example in which the process is performed in the order of “increasing the pressure in the cavity 15 starts”→“returning the posture of the mold 10 starts”→“increasing the pressure in the cavity 15 ends”→“returning the posture of the mold 10 ends”. Tilt decreasing step S34 in the example shown in FIG. 10A starts after gas increasing step S33 starts, and ends after gas increasing step S33 ends and before gas decreasing step S35 starts.

FIG. 10B shows an example in which the process is performed in the order of “increasing the pressure in the cavity 15 starts”→“returning the posture of the mold 10 starts”→“increasing the pressure in the cavity 15 and returning the posture of the mold 10 end at the same time”. Tilt decreasing step S34 in the example shown in FIG. 10B starts after gas increasing step S33 starts, and ends at the same time as gas increasing step S33 ends. Note that tilt decreasing step S34 may start after gas increasing step S33 starts, and end before gas increasing step S33 ends.

FIG. 10C shows an example in which the process is performed in the order of “increasing the pressure in the cavity 15 and returning the posture of the mold 10 start at the same time”→“increasing the pressure in the cavity 15 ends”→“returning the posture of the mold 10 ends”. Tilt decreasing step S34 in the example shown in FIG. 10C starts at the same time as gas increasing step S33 starts, and ends after gas increasing step S33 ends and before gas decreasing step S35 starts.

FIG. 10D shows an example in which the process is performed in the order of “increasing the pressure in the cavity 15 and returning the posture of the mold 10 start at the same time”→“increasing the pressure in the cavity 15 and returning the posture of the mold 10 end at the same time”. Tilt decreasing step S34 in the example shown in FIG. 10D starts at the same time as gas increasing step S33 starts, and ends at the same time as gas increasing step S33 ends. Note that tilt decreasing step S34 may start after gas increasing step S33 starts. Further, tilt decreasing step S34 may end before gas increasing step S33 ends.

Five examples of the imprint process (contact process) according to this embodiment have been described above with reference to FIGS. 9A to 9D and 10A to 10D. All the five examples are common in that the deformation amount of the contact surface 16 is increased after the contact surface 16 of the mold 10 and the imprint material on the substrate start to contact each other, and the posture of the mold 10 is returned in the state in which the deformation amount of the contact surface 16 has been increased. In any of the examples, the start of returning the posture of the mold 10 (that is, the start of tilt decreasing step S34) never precedes the start of increasing the pressure in the cavity 15 (that is, the start of gas increasing step S33). Further, the end of returning the posture of the mold 10 (that is, the end of tilt decreasing step S34) never succeeds the start of decreasing the pressure in the cavity 15 (that is, the start of gas decreasing step S35).

The orders of the start and end of increasing the pressure in the cavity 15 and the start and end of returning the posture of the mold 10 have been described above. There can be several ways to decide the specific timings of performing these steps in the contact process (contact starting process and pressing process). For example, the timing may be decided using images showing the imprint material spreading on the contact surface 16 at respective elapsed times obtained by an image capturing element (not shown) that captures the imprint material spreading on the contact surface 16 in real time. By comparing the void occurrence location on the substrate 11 after formation of the imprint material and the images showing the imprint material spreading on the contact surface 16 at respective elapsed times, the start time and end time of increasing the pressure in the cavity 15 and the start time and end time of returning the posture of the mold 10 may be adjusted.

As has been described above, in the imprint process (contact process) of Example 1, the gas increasing step of further supplying the gas into the cavity 15 to increase the deformation amount of the contact surface 16 is performed after the contact surface 16 and the imprint material on the substrate 11 start to contact each other. Further, in the imprint process (contact process) of Example 1, the tilt decreasing step of decreasing the tilt of the mold 10 with respect to the substrate 11 can be performed in the period from the start of the gas increasing step to the start of the gas decreasing step. The gas decreasing step is a step of decreasing the gas in the cavity 15 to decrease the deformation amount of the contact surface 16. With this, for example, in the imprint process (contact process) for the deficient shot region 22, it is possible to reduce void occurrence and accurately form the imprint material on the substrate.

### Example 2

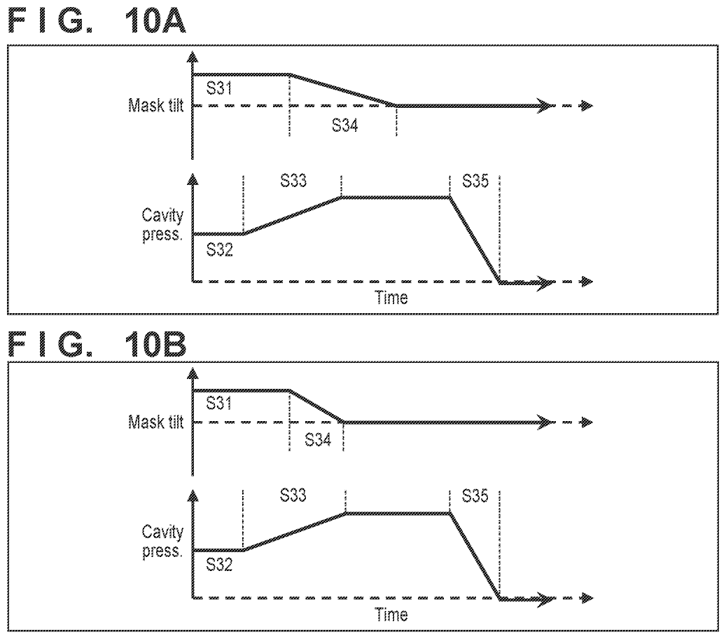

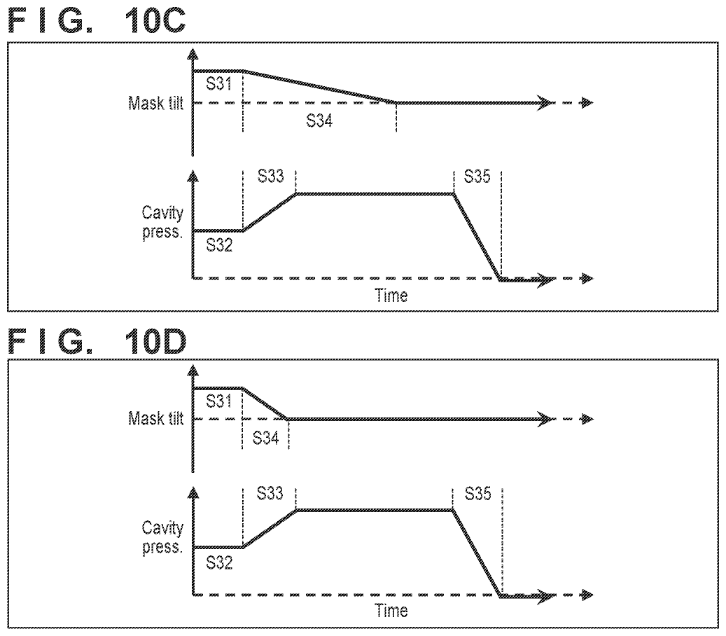

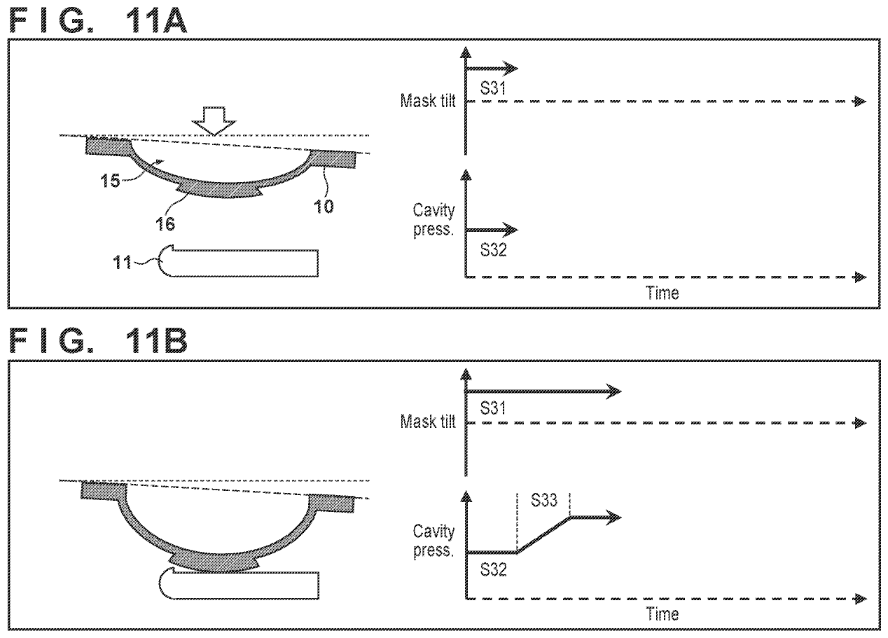

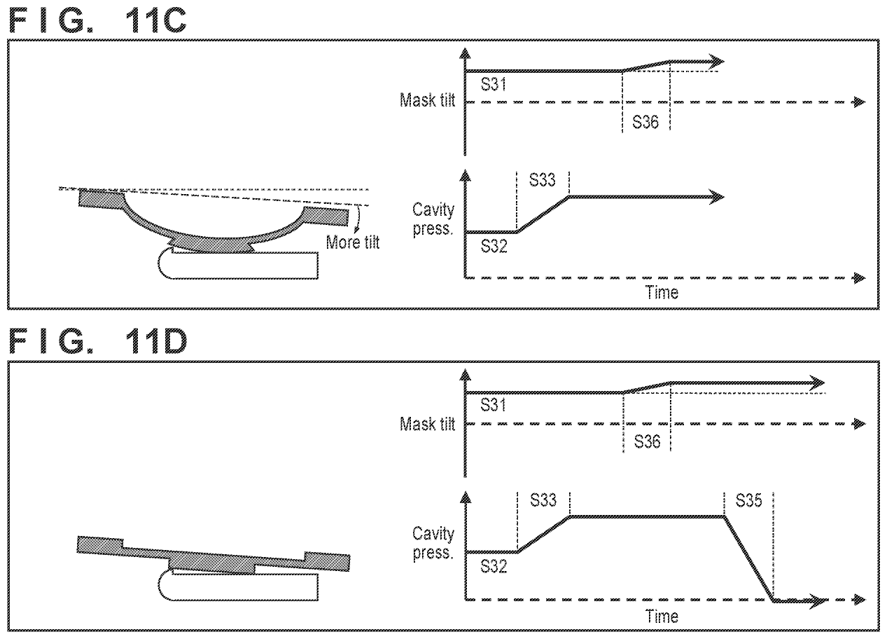

Example 2 according to the present invention will be described below. In Example 2, posture control of the mold 10 in a case in which the edge portion of the substrate 11 is higher than the pattern forming surface will be described with reference to FIGS. 11A to 11D. The pattern forming surface of the substrate 11 is the surface on which the imprint material is arranged and the pattern of the mold 10 is to be transferred (formed). The edge portion of the substrate 11 is the portion surrounding the pattern forming surface. In the substrate 11 shown in FIGS. 11A to 11D, the edge portion has been made higher than the pattern forming surface of the substrate 11 through the process manufacturing process. Example 2 is a method effective in performing the imprint process (contact process) on the deficient shot region 22 of such the substrate 11. Note that Example 2 basically takes over Example 1, and is the same as described in Example 1 except matters to be described below.

For the substrate 11 in which the edge portion is higher than the pattern forming surface, if the mold 10 is returned to the posture facing straight with respect to the substrate 11 as in Example 1 described above, the substrate 11 and the contact surface 16 of the mold 10 can contact each other without intervening the imprint material. In this situation, when the substrate driver 13 drives the substrate 11 to perform alignment (overlay) between the contact surface 16 of the mold 10 and the shot region on the substrate 11, a large force that deforms the contact surface 16 is generated in the X and Y directions, and this can decrease the alignment accuracy (overlay accuracy). According to Example 2, this problem can be avoided.

In FIGS. 11A and 11B, as in FIGS. 9A and 9B described in Example 1, the pressure in the cavity 15 and the posture (tilt) of the mold 10 are controlled, and spreading the imprint material is started. Then, in FIG. 11C, after the contact surface 16 of the mold 10 and the imprint material on the substrate start to contact each other, tilt increasing step S36 is performed during the process of spreading the imprint material on the contact surface 16. Tilt increasing step S36 is a step of further tilting the mold 10 with respect to the substrate 11 such that the contact surface 16 does not contact the edge portion of the substrate 11.

In FIG. 11D, in order to spread the imprint material over the entire contact surface 16, the pressure in the cavity 15 is decreased to make the contact surface 16 deformed into the convex shape become the shape facing straight with respect to the substrate 11 or adjusted for overlay with the substrate 11. That is, so as to make the contact surface 16 and the substrate 11 parallel to each other, the mold deforming unit 14 decreases the gas in the cavity 15, thereby decreasing the pressure in the cavity 15 and decreasing the deformation amount of the contact surface 16 of the mold 10 (gas decreasing step S35). As for the tilt of the mold 10, the imprint material on the substrate is cured with the mold 10 further tilted in tilt increasing step S36 shown in FIG. 11C, and the tilt decreasing step of decreasing the tilt of the mold 10 is not performed.

### Embodiment of Article Manufacturing Method

An article manufacturing method according to the embodiment of the present invention is suitable for manufacturing an article, for example, a microdevice such as a semiconductor device or a device having a microstructure. The article manufacturing method according to this embodiment includes a forming step of forming, using the above-described forming method (imprint method), a composition (imprint material) on a substrate, and a processing step of processing the substrate having the composition formed in the forming step. The manufacturing method further includes other known steps (oxidation, film formation, deposition, doping, planarization, etching, resist removal, dicing, bonding, packaging, and the like). The article manufacturing method of this embodiment is more advantageous than the conventional methods in at least one of the performance, quality, productivity, and production cost of the article.

The pattern of a cured product formed using the above-described forming method (imprint method) is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, an SRAM, a flash memory, and an MRAM and semiconductor elements such as an LSI, a CCD, an image sensor, and an FPGA. Examples of the mold are a mold for imprint and the like.

The pattern of the cured product is directly used as the constituent member of at least some of the above-described articles or used temporarily as a resist mask. After etching or ion implantation is performed in the substrate processing step, the resist mask is removed.

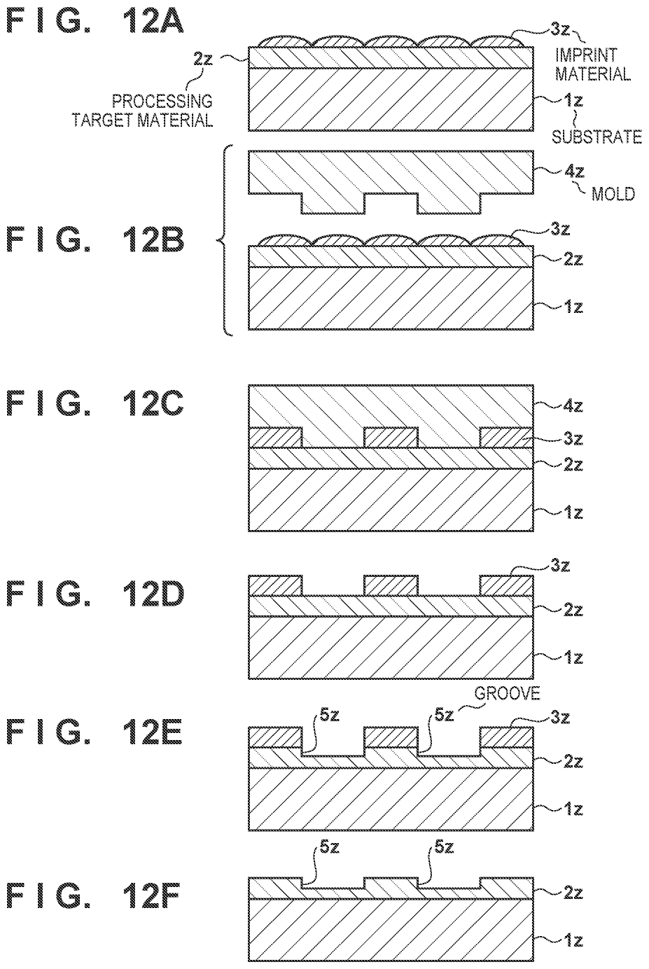

Next, a specific method of manufacturing an article using an imprint method as the forming method will be described. As shown in FIG. 12A, a substrate 1z such as a silicon wafer with a target material 2z to be processed, such as an insulator, formed on the surface is prepared. Next, an imprint material 3z is applied to the surface of the target material 2z by an inkjet method or the like. A state in which the imprint material 3z is applied as a plurality of droplets onto the substrate is shown here.

As shown in FIG. 12B, a side of a mold 4z for imprint, where a pattern with concave and convex portions is formed, is directed to face the imprint material 3z on the substrate. As shown in FIG. 12C, the mold 4z and the substrate 1z to which the imprint material 3z is applied are brought into contact with each other, and a pressure is applied. The gap between the mold 4z and the target material 2z is filled with the imprint material 3z. In this state, by irradiating the imprint material 3z with energy for curing through the mold 4z, the imprint material 3z is cured.

As shown in FIG. 12D, after the imprint material 3z is cured, the mold 4z is separated from the substrate 1z. Then, the pattern of the cured product of the imprint material 3z is formed on the substrate 1z. In the pattern of the cured product, the concave portion of the mold corresponds to the convex portion of the cured product, and the convex portion of the mold corresponds to the concave portion of the cured product. That is, the pattern with concave and convex portions in the mold 4z is transferred to the imprint material 3z.

As shown in FIG. 12E, by performing etching using the pattern of the cured product as an etching resistant mask, a portion of the surface of the target material 2z where the cured product does not exist or remains thin is removed to form a groove 5z. As shown in FIG. 12F, by removing the pattern of the cured product, an article with the grooves 5z formed in the surface of the target material 2z can be obtained. Here, the pattern of the cured product is removed. However, instead of removing the pattern of the cured product after processing, it may be used as, for example, an interlayer dielectric film included in a semiconductor element or the like, that is, a constituent member of an article.

### Embodiment of Planarization Process

In the above-described embodiment, a circuit pattern transfer mold on which a pattern with concave and convex portions is formed has been described as the mold. However, the mold may be a mold (plane template) having, as the contact surface, a flat surface where no pattern with concave and convex portions is formed. The plane template is used in a planarization apparatus (forming apparatus) that performs a planarization process (forming process) of performing forming such that a composition on a substrate is planarized by the flat surface. The planarization process includes a step of curing a curable composition by light irradiation or heating in a state in which the flat surface (contact surface) of the plane template is in contact with the curable composition supplied onto the substrate. As described above, this embodiment can be applied to a forming apparatus configured to form a composition on a substrate using a plane template.

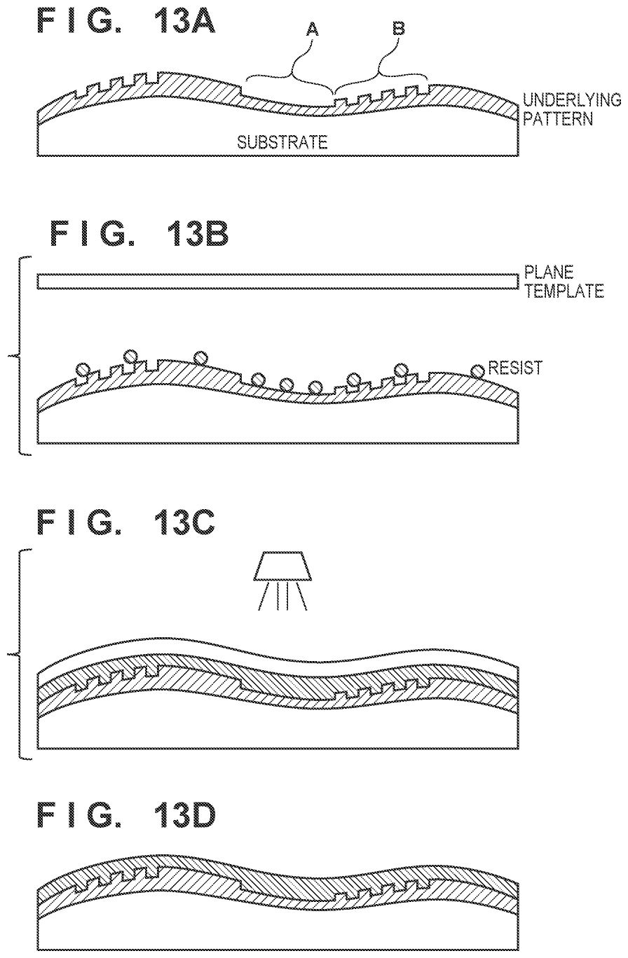

The underlying pattern on the substrate has an uneven profile derived from the pattern formed in the previous step. In particular, with the recent multilayered structure of a memory element, the substrate (process wafer) may have a step of about 100 nm. The step derived from a moderate undulation of the entire substrate can be corrected by the focus following function of an exposure apparatus (scanner) used in the photolithography step. However, an unevenness with a small pitch fitted in the exposure slit area of the exposure apparatus directly consumes the DOF (Depth Of Focus) of the exposure apparatus. As a conventional technique of planarizing the underlying pattern of a substrate, a technique of forming a planarization layer, such as SOC (Spin On Carbon) or CMP (Chemical Mechanical Polishing), is used. In the conventional technique, however, as shown in FIG. 13A, an unevenness suppressing rate of only 40% to 70% is obtained in the boundary portion between an isolated pattern region A and a repetitive dense (concentration of a line & space pattern) pattern region B, and sufficient planarization performance cannot be obtained. The unevenness difference of the underlying pattern caused by the multilayered structure tends to further increase in the future.

As a solution to this problem, U.S. Pat. No. 9,415,418 proposes a technique of forming a continuous film by application of a resist serving as a planarization layer by an inkjet dispenser and pressing by a plane template. Also, U.S. Pat. No. 8,394,282 proposes a technique of reflecting a topography measurement result on a substrate side on density information for each position to instruct application by an inkjet dispenser. An imprint apparatus IMP can particularly be applied as a planarization processing (planarization) apparatus for performing local planarization in a substrate surface by pressing a plane template as the mold against an uncured resist applied in advance.

FIG. 13A shows a substrate before planarization processing. In the isolated pattern region A, the area of a pattern convex portion is small. In the repetitive dense pattern region B, the ratio of the area of a pattern convex portion to the area of a pattern concave portion is 1:1. The average height of the isolated pattern region A and the repetitive dense pattern region B changes depending on the ratio of the pattern convex portion.

FIG. 13B shows a state in which the resist that forms the planarization layer is applied to the substrate. FIG. 13B shows a state in which the resist is applied by an inkjet dispenser based on the technique proposed in U.S. Pat. No. 9,415,418. However, a spin coater may be used to apply the resist. In other words, the imprint apparatus IMP can be applied if a step of pressing a plane template against an uncured resist applied in advance to planarize the resist is included.

As shown in FIG. 13C, the plane template is made of glass or quartz that passes ultraviolet light, and the resist is cured by irradiation of ultraviolet light from a light source. For the moderate unevenness of the entire substrate, the plane template conforms to the profile of the substrate surface. After the resist is cured, the plane template is separated from the resist, as shown in FIG. 13D.

### OTHER EMBODIMENTS

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-030173 filed on Feb. 28, 2022, which is hereby incorporated by reference herein in its entirety.

What is claimed is:

1. A forming method of forming a composition on a substrate using a mold, wherein the mold has a contact surface that is to be brought into contact with the composition on the substrate and a cavity provided in a surface on an opposite side of the contact surface, the method comprising:
supplying a gas into the cavity so as to increase a pressure in the cavity to deform the contact surface into a convex shape toward the substrate;
relatively tilting the mold with respect to the substrate;
bringing the contact surface and the composition on the substrate into contact with each other in a state in which the contact surface has been deformed in the supplying the gas and the mold has been tilted in the relatively tilting; and
further supplying the gas into the cavity so as to increase a deformation amount of the contact surface after the contact surface and the composition start to contact each other in the bringing.

2. The method according to claim 1, further comprising:
decreasing the gas in the cavity so as to decrease the deformation amount of the contact surface after the further supplying the gas; and
decreasing a tilt of the mold with respect to the substrate,
wherein the decreasing the tilt is performed in a period from a start of the further supplying the gas to a start of the decreasing the gas.

3. The method according to claim 2, wherein
the decreasing the tilt is performed so as to end after the further supplying the gas ends.

4. The method according to claim 3, wherein
the decreasing the tilt is performed so as to start after the further supplying the gas ends.

5. The method according to claim 3, wherein
the decreasing the tilt is performed so as to start at the same time as the further supplying the gas ends or before the further supplying the gas ends.

6. The method according to claim 2, wherein
the decreasing the tilt is performed so as to end at the same time as the further supplying the gas ends or before the further supplying the gas ends.

7. The method according to claim 2, wherein
the decreasing the gas and the decreasing the tilt are performed such that the entire contact surface contacts the composition.

8. The method according to claim 1, further comprising
increasing a relative tilt of the mold with respect to the substrate after the further supplying the gas.

9. The method according to claim 8, further comprising:
decreasing the gas in the cavity so as to decrease the deformation amount of the contact surface after the increasing the relative tilt; and
curing the composition in a state in which the contact surface and the composition are in contact with each other after the decreasing the gas,
wherein the curing is performed while maintaining a state in which the relative tilt of the mold with respect to the substrate has been increased in the increasing the relative tilt.

10. The method according to claim 1, wherein
the further supplying the gas is performed in a state in which a part of the contact surface and the composition are in contact with each other during the bringing.

11. The method according to claim 1, wherein
the supplying the gas and the relatively tilting are performed such that the contact starts at a target location on the substrate in the bringing.

12. An article manufacturing method comprising:
forming a composition on a substrate using a forming method defined in claim 1;
processing the substrate on which the composition has been formed in the forming; and
manufacturing an article from the processed substrate.

13. A forming apparatus that forms a composition on a substrate using a mold, wherein the mold has a contact surface that is to be brought into contact with the composition on the substrate and a cavity provided in a surface on an opposite side of the contact surface, the apparatus comprising:
a gas supplier configured to supply a gas into the cavity so as to increase a pressure in the cavity to deform the contact surface into a convex shape toward the substrate;
a tilt changer configured to relatively tilt the mold with respect to the substrate; and
a controller configured to control contact between the contact surface and the composition on the substrate,
wherein the controller is configured to:
bring the contact surface and the composition on the substrate into contact with each other in a state in which the contact surface has been deformed by the gas supplier and the mold has been tilted by the tilt changer, and
further supplies the gas into the cavity by the gas supplier so as to increase a deformation amount of the contact surface after the contact surface and the composition start to contact each other.

14. The apparatus according to claim 13, wherein
the contact surface includes a pattern to be transferred to the composition on the substrate, and
the apparatus forms a pattern in the composition on the substrate by bringing the contact surface into contact with the composition on the substrate.

15. The apparatus according to claim 13, wherein
the contact surface is a flat surface, and
the apparatus planarizes the composition on the substrate by bringing the contact surface into contact with the composition on the substrate.
